(19) United States
(12) Patent Application Publication
(10) Pub. No.: US 2026/0353816 A1
(43) Pub. Date: Nov. 5, 2026

(54) INTEGRATED CAPACITOR

(71) Applicant: ELSPES Inc., Daejeon (KR)

(72) Inventors: Dong Ki LEE, Hwaseong-si (KR); Hee Il CHAE, Hwaseong-si (KR); Eun Joo KO, Hwaseong-si (KR); Ui Hwan KIM, Hwaseong-si (KR); Tae Dong KIM, Hwaseong-si (KR); Yeong Lyeol PARK, Yongin-si (KR)

(21) Appl. No.: 19/552,495

(22) Filed: Feb. 27, 2026

(30) Foreign Application Priority Data
May 2, 2025 (KR) 10-2025-0058095

(51) Int. Cl. H10D 89/60

(52) U.S. Cl. CPC H10D 89/911; H10D 89/611

(57) ABSTRACT

The present disclosure relates to a semiconductor package. A semiconductor package of the present disclosure includes a package substrate, a first semiconductor die disposed on the package substrate, a second semiconductor die disposed to be spaced from the first semiconductor die on the package substrate, and a capacitor chip disposed on at least one electrical path between the first semiconductor die and the second semiconductor die on the package substrate, wherein the capacitor chip includes a substrate, at least one trench capacitor disposed on the substrate, and a diode disposed to be spaced from the at least one trench capacitor on the substrate, one electrode of the at least one trench capacitor is connected to a cathode electrode of the diode and the first semiconductor die, the other electrode of the at least one trench capacitor is connected to the second semiconductor die, and an anode electrode of the diode is grounded, thereby blocking common-mode noise and improving electromagnetic interference (EMI) performance and signal integrity in chip-to-chip communication.

### CROSS-REFERENCE TO RELATED APPLICATION

This application claims priority to and the benefit of Korean Patent Application No. 2025-0058095, filed on May 2, 2025, the disclosure of which is incorporated herein by reference in its entirety.

### BACKGROUND

### 1. Field of the Invention

The present disclosure relates to a semiconductor package, and more particularly, to a semiconductor package including a coupling capacitor chip in which a diode and a capacitor are integrated.

### 2. Discussion of Related Art

In recent years, with rapid development of portable electronic devices such as smartphones, tablets, and wearable devices, demand for a technology that can simultaneously satisfy high-performance and low-power characteristics while achieving size reduction has increased. In response to such demand, semiconductor devices have been developed to match the trends of reducing the size and increasing the integration of electronic devices, but existing multi-chip design methods have caused problems such as an increase in complexity of connection between components, a delay in data transfer, and an increase in power consumption.

To address such problems, a system-on-chip (SoC) structure in which a central processing unit (CPU), a graphics processing unit (GPU), a digital signal processor (DSP), a neural processing unit (NPU), a radio frequency (RF) circuit, a communication modem (LTE/5G), a memory block, and the like are integrated on a single chip has been proposed. By simplifying a chip-to-chip interface, the SoC structure has advantages that the circuit complexity is reduced, and the operation speed and power efficiency are improved. However, the SoC design method has a technical limitation that heterogeneous components should be integrated with a single process. For example, while a 14 nm process is required for some components, a 28 nm process or a 40 nm process may be sufficient for implementing some other components. In this case, when all the components are integrated with the 14 nm process, a problem may occur in which excessive manufacturing costs and resources are consumed for a chip that can also be implemented with the 28 nm process or the 40 nm process. Also, when heterogeneous components are designed based on different materials, because processes suitable for characteristics of each material are required, process optimization is difficult, and the overall manufacture efficiency and yield may decrease when the heterogeneous components are implemented with a single process.

Therefore, there is a need for a technology for addressing the above-described problems.

Meanwhile, the above-described background art is technical information that was possessed by the inventors to derive the present disclosure or acquired by the inventors in the course of deriving the present disclosure, and the background art is not necessarily a known art that was open to the general public prior to filing of the present disclosure.

### RELATED ART DOCUMENT

### Patent Document

(Patent Document 1) U.S. Patent Publication No. 2013-0134607 (May 30, 2013)

### SUMMARY OF THE INVENTION

The present disclosure is directed to providing a semiconductor package capable of high-speed signal transmission while reducing complexity of connection between a plurality of semiconductor dies.

The present disclosure is also directed to providing a semiconductor package capable of integrating heterogeneous semiconductor dies implemented based on different processes or materials into a single package.

The present disclosure is also directed to providing a semiconductor package capable of preventing problems of a decrease in manufacture and production efficiency and a decrease in power efficiency by mounting semiconductor dies each formed with an optimized process.

Objectives of the present disclosure are not limited to those mentioned above, and other unmentioned objectives should be clearly understood by those of ordinary skill in the art from the description below.

According to one aspect of the present disclosure, there is provided a semiconductor package including a package substrate, a first semiconductor die disposed on the package substrate, a second semiconductor die disposed to be spaced from the first semiconductor die on the package substrate, and a capacitor chip disposed on at least one electrical path between the first semiconductor die and the second semiconductor die on the package substrate, wherein the capacitor chip includes a substrate, at least one trench capacitor disposed on the substrate, and a diode disposed to be spaced from the at least one trench capacitor on the substrate, one electrode of the at least one trench capacitor is connected to a cathode electrode of the diode and the first semiconductor die, the other electrode of the at least one trench capacitor is connected to the second semiconductor die, and an anode electrode of the diode is grounded.

According to another aspect of the present disclosure, the first semiconductor die and the second semiconductor die may be heterogeneous chips having different driving voltages.

According to still another aspect of the present disclosure, the diode may include a first doping region doped with an N-type impurity and a second doping region doped with a P-type impurity, the first doping region may be connected to the cathode electrode, and the second doping region may be connected to the anode electrode.

According to yet another aspect of the present disclosure, the diode may further include a P-type well region, the first doping region and the second doping region may be disposed in the P-type well region, and the second doping region may be disposed to be spaced from the first doping region to surround the first doping region and may have a doping concentration higher than a doping concentration of the P-type well region.

According to yet another aspect of the present disclosure, the at least one trench capacitor may be disposed in a plurality of first trenches located on the substrate, the diode may further include a second trench disposed between the first doping region and the second doping region, and the first trenches and the second trench may be formed with the same process.

According to yet another aspect of the present disclosure, the first doping region and the second doping region may be disposed in contact, and the diode may be a Zener diode.

According to yet another aspect of the present disclosure, the diode may further include an ohmic contact layer disposed on upper surfaces of the first doping region and the second doping region, and the ohmic contact layer may consist of a Ti/TiN stacking structure.

According to yet another aspect of the present disclosure, the diode may be disposed to be surrounded by the at least one trench capacitor.

According to yet another aspect of the present disclosure, at one side of the at least one trench capacitor, the diode may be disposed along an edge of the one side.

According to yet another aspect of the present disclosure, the diode may be disposed to surround the at least one trench capacitor.

According to yet another aspect of the present disclosure, the at least one trench capacitor may include a plurality of trench capacitors, and the diode may be disposed between the plurality of trench capacitors.

According to yet another aspect of the present disclosure, the plurality of trench capacitors may be connected in parallel, and a single diode formed as one body may be disposed between different pairs of the plurality of trench capacitors.

According to yet another aspect of the present disclosure, when the at least one electrical path is provided as a plurality of electrical paths, the plurality of electrical paths may be connected to a single capacitor chip, and the plurality of electrical paths may each connect the first semiconductor die and the second semiconductor die through one of the plurality of trench capacitors.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a top view of a semiconductor package according to one embodiment of the present disclosure;

FIG. 2 is a schematic top view of a capacitor chip of FIG. 1;

FIG. 3 is a schematic cross-sectional view of the capacitor chip of FIG. 2 along line III-III′ of FIG. 2;

FIG. 4 is a cross-sectional view of the capacitor chip of FIG. 2 along line III-III′ of FIG. 2 according to another embodiment;

FIG. 5 is a cross-sectional view of the capacitor chip of FIG. 2 along line III-III′ of FIG. 2 according to still another embodiment;

FIG. 6 is a schematic top view of a capacitor chip on which a diode is disposed to be surrounded by a trench capacitor according to another embodiment of the present disclosure;

FIG. 7 is a schematic top view of a capacitor chip on which a diode is disposed along an edge of one side of a trench capacitor according to still another embodiment of the present disclosure;

FIG. 8 is a schematic top view of a capacitor chip on which a diode is disposed to surround a trench capacitor according to yet another embodiment of the present disclosure;

FIG. 9 is a top view of a semiconductor package according to another embodiment of the present disclosure;

FIG. 10 is a schematic top view of a capacitor chip of FIG. 9;

FIG. 11 is a top view of a semiconductor package according to still another embodiment of the present disclosure; and

FIG. 12 is a schematic top view of a capacitor chip of FIG. 11.

### DETAILED DESCRIPTION OF EXEMPLARY EMBODIMENTS

Advantages and features of the present disclosure and methods of achieving them will become apparent with reference to the embodiments described below in detail in conjunction with the accompanying drawings. However, the present disclosure is not limited to the embodiments disclosed below, but may be implemented in various different forms, and these embodiments are provided only to allow the disclosure of the present disclosure to be complete, and to completely inform those of ordinary skill in the art to which the present disclosure pertains of the scope of the invention, and the present disclosure is only defined by the scope of the claims.

Since the shapes, sizes, proportions, angles, numbers, and the like disclosed in the drawings for describing embodiments of the present disclosure are only examples, the present disclosure is not limited to the illustrated items. Further, in describing the present disclosure, when it is determined that a detailed description of related known technology may unnecessarily obscure the gist of the present disclosure, the detailed description thereof will be omitted. Where “including,” “having,” “consisting of,” and the like are used in the present disclosure, other parts may be added unless a more limiting term like “only” is used. A case in which a component is expressed in a singular form includes a plural form, and vice versa, unless explicitly stated otherwise.

In interpreting the components, it should be understood that an error range is included even when there is no separate explicit description.

Although terms “first,” “second,” and the like may be used to describe various components, these components are not limited by these terms. These terms are only used to distinguish one component from another component. Accordingly, a first component mentioned below may also be a second component, and vice versa, within the technical spirit of the present disclosure.

The same reference numerals indicate the same components throughout the disclosure unless otherwise specified.

Features of various embodiments of the present disclosure may be partially or entirely coupled or combined with each other, and technically, various linkages and operations are possible as can be readily understood by those of ordinary skill in the art, and the embodiments may be implemented independently of each other or together in an interrelated relationship.

Hereinafter, the present disclosure will be described in detail with reference to the accompanying drawings.

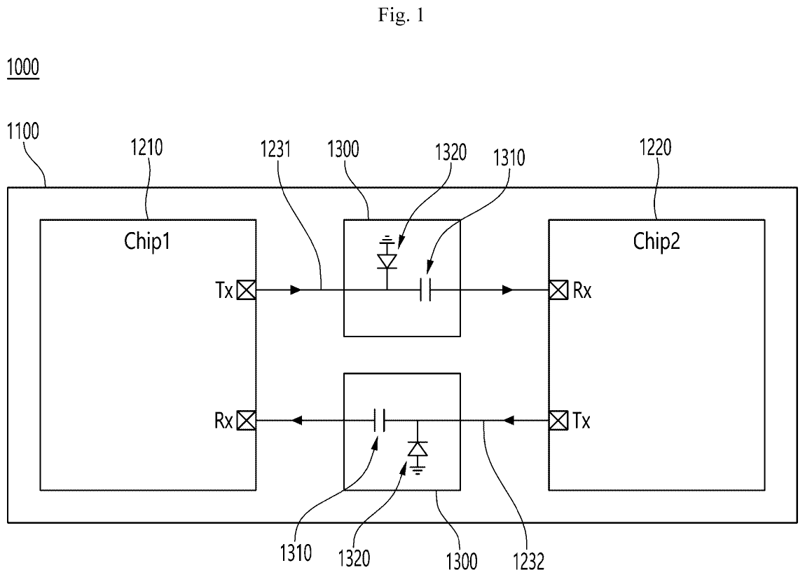

FIG. 1 is a top view of a semiconductor package according to one embodiment of the present disclosure.

Referring to FIG. 1, a semiconductor package 1000 includes a package substrate 1100, a first semiconductor die 1210, a second semiconductor die 1220, and capacitor chips 1300.

The semiconductor package 1000 may be a device that protects the semiconductor dies 1210 and 1220 and connects the semiconductor dies 1210 and 1220 to an external circuit. Specifically, the semiconductor package 1000 may be a device that integrates heterogeneous semiconductor dies 1210 and 1220 in a single package and electrically connects the semiconductor dies 1210 and 1220 to each other or the semiconductor dies 1210 and 1220 to an external circuit. For example, the semiconductor package 1000 may be a system-in-package (SiP).

Referring to FIG. 1, the package substrate 1100 is a substrate for a semiconductor package. The package substrate 1100 may connect one or more semiconductor dies 1210 and 1220 disposed on the package substrate 1100 to an external device or other semiconductor dies or components. Specifically, the package substrate 1100 may connect heterogeneous components disposed on the package substrate 1100 to each other through bridge wiring or may connect heterogeneous components disposed on the package substrate 1100 to an external device through redistribution wiring.

The package substrate 1100 may be a printed circuit board (PCB), an organic substrate, a ceramic substrate, a glass substrate, a silicon substrate, a tape wiring substrate, and the like. For example, the package substrate 1100 may be any one of a one-sided PCB, a double-sided PCB, and a multi-layer PCB.

According to various embodiments of the present disclosure, an interposer (not illustrated) may be disposed on the package substrate 1100. Specifically, the interposer may be disposed between the first and second semiconductor dies 1210 and 1220 and the package substrate 1100. The interposer may connect the first semiconductor die 1210 and the second semiconductor die 1220 to the package substrate 1100 through a through integrated fan-out via (TIV) or redistribution wiring.

Referring to FIG. 1, the first semiconductor die 1210 and the second semiconductor die 1220 may be various electronic components, chips, or modules. For example, the first semiconductor die 1210 and the second semiconductor die 1220 may include at least one of a CPU, a GPU, an NPU, a memory, a communication module, and an RF module. In some cases, the first semiconductor die 1210 and the second semiconductor die 1220 may be different electronic components. Specifically, the first semiconductor die 1210 and the second semiconductor die 1220 may be heterogeneous semiconductor dies made through different manufacturing processes. Preferably, the first semiconductor die 1210 and the second semiconductor die 1220 may be different-sized chips, dies, or modules made through a nano-scale process. For example, the first semiconductor die 1210 may be a processor, and the second semiconductor die 1220 may be a memory element. Specifically, the first semiconductor die 1210 may be a processor manufactured through a 14 nm process, and the second semiconductor die 1220 may be a memory element manufactured through a 40 nm process.

By including the first semiconductor die 1210 and the second semiconductor die 1220 that are heterogeneous, the semiconductor package 1000 according to one embodiment of the present disclosure allows each of the semiconductor dies 1210 and 1220 to be efficiently arranged for a specialized task. Also, by having chips or modules manufactured through different processes or having different sizes arranged on a single package substrate 1100, the semiconductor package 1000 can improve the degree of integration, efficiency of manufacturing process, and yield.

The first semiconductor die 1210 and the second semiconductor die 1220 may have different driving voltages. Specifically, the first semiconductor die 1210 and the second semiconductor die 1220 may have power supply voltages (VDD) at different levels or may have reference voltages (VSS) at different levels. That is, the first semiconductor die 1210 and the second semiconductor die 1220 may be driven by voltages at different levels.

The first semiconductor die 1210 and the second semiconductor die 1220 may be disposed on the package substrate 1100. In some cases, the first semiconductor die 1210 and the second semiconductor die 1220 may be disposed on an upper surface of the interposer (not illustrated) disposed on the package substrate 1100. Specifically, the first semiconductor die 1210 and the second semiconductor die 1220 may be disposed to be spaced from each other on the package substrate 1100 or the interposer. In some cases, the first semiconductor die 1210 and the second semiconductor die 1220 may be disposed adjacent to each other. Also, the first semiconductor die 1210 and the second semiconductor die 1220 may be disposed in contact with each other. Accordingly, the semiconductor package 1000 can facilitate reducing the size and increasing the integration of electronic devices and can more efficiently integrate functions between the semiconductor dies 1210 and 1220.

The first semiconductor die 1210 and the second semiconductor die 1220 may be electrically connected. Specifically, one or more electrical paths 1230 may be formed between the first semiconductor die 1210 and the second semiconductor die 1220. The first semiconductor die 1210 and the second semiconductor die 1220 may perform chip-to-chip communication through the one or more electrical paths 1230.

Referring to FIG. 1, the one or more electrical paths 1230 may include a first electrical path 1231 and a second electrical path 1232. The first electrical path 1231 may be disposed between a data transmitter of the first semiconductor die 1210 and a data receiver of the second semiconductor die 1220. The second electrical path 1232 may be disposed between a data receiver of the first semiconductor die 1210 and a data transmitter of the second semiconductor die 1220. That is, the first electrical path 1231 may be a path along which the first semiconductor die 1210 transmits data to the second semiconductor die 1220, and the second electrical path 1232 may be a path along which the second semiconductor die 1220 transmits data to the first semiconductor die 1210. In some cases, the first semiconductor die 1210 and the second semiconductor die 1220 may transmit and receive data to and from each other through a single electrical path. That is, the first electrical path 1231 may serve as the path along which the second semiconductor die 1220 transmits data to the first semiconductor die 1210 as well as the path along which the first semiconductor die 1210 transmits data to the second semiconductor die 1220.

Referring to FIG. 1, the capacitor chips 1300 may be chips each including a capacitor 1310 and a diode 1320. Specifically, the capacitor chips 1300 may be passive element integrated chips formed through a separate manufacturing process. That is, the capacitor chips 1300 may each be a passive element integrated chip on which the capacitor 1310 and the diode 1320 are formed on a single substrate independent from the package substrate 1100 or the interposer (not illustrated). In some cases, the capacitor chips 1300 may be passive element integrated chips integrally formed with the package substrate 1100 or the interposer.

The capacitor chips 1300 may be disposed between the first semiconductor die 1210 and the second semiconductor die 1220. Specifically, the capacitor chips 1300 may be disposed between the first semiconductor die 1210 and the second semiconductor die 1220 on the package substrate 1100. In some cases, the capacitor chips 1300 may be disposed in the package substrate 1100 or disposed in the interposer (not illustrated). For example, the capacitor chips 1300 may be embedded in the package substrate 1100 or the interposer and may be disposed on a lower portion of the first semiconductor die 1210 or a lower portion of the second semiconductor die 1220.

The capacitor chips 1300 may be disposed on the one or more electrical paths 1230 between the first semiconductor die 1210 and the second semiconductor die 1220. Specifically, the capacitor chips 1300 may each be disposed on one of the first electrical path 1231 and the second electrical path 1232 between the first semiconductor die 1210 and the second semiconductor die 1220. That is, the capacitor chips 1300 may be disposed on a chip-to-chip communication line between the first semiconductor die 1210 and the second semiconductor die 1220.

Referring to FIG. 1, the capacitor 1310 may be various types of capacitors. For example, the capacitor 1310 may be any one of a trench capacitor, a silicon capacitor, an embedded capacitor, and a thin film capacitor. Preferably, the capacitor 1310 may be a deep trench capacitor (DTC). Accordingly, by including a DTC that is able to secure a capacity in the vertical direction and is advantageous for size reduction, the semiconductor package 1000 can efficiently provide a capacitance to semiconductor dies in a limited space.

The capacitor 1310 may be disposed in the one or more electrical paths 1230 between the first semiconductor die 1210 and the second semiconductor die 1220. Specifically, the capacitor 1310 may be disposed so that one electrode is connected to the first semiconductor die 1210 through the electrical path 1230 and the other electrode is connected to the second semiconductor die 1220 through the electrical path 1230.

Referring to FIG. 1, the diode 1320 may be various types of diodes. For example, the diode 1320 may be any one of a rectifier diode, a Schottky diode, a Zener diode, an electrostatic discharge (ESD) protection diode, and a transient voltage suppression (TVS) diode. Preferably, the diode 1320 may be an ESD protection diode made of a rectifier diode, a Schottky diode, or a Zener diode.

The diode 1320 may be disposed on the one or more electrical paths 1230 between the first semiconductor die 1210 and the second semiconductor die 1220. Specifically, the diode 1320 may be disposed so that one end is connected to the electrical path 1230 and the other end is grounded. More specifically, the diode 1320 may be disposed so that a cathode electrode is connected to any one of the semiconductor dies 1210 and 1220 and the capacitor 1310 and an anode electrode is grounded. For example, when the capacitor 1310 is disposed on the first electrical path 1231, the diode 1320 may be disposed so that the cathode electrode is connected to one electrode of the capacitor 1310 and the first semiconductor die 1210 and the anode electrode is grounded. Also, when the capacitor 1310 is disposed on the second electrical path 1232, the diode 1320 may be disposed so that the cathode electrode is connected to the other electrode of the capacitor 1310 and the second semiconductor die 1220 and the anode electrode is grounded. In some cases, when the capacitor 1310 is disposed on the first electrical path 1231, the diode 1320 may be disposed so that the cathode electrode is connected to the other electrode of the capacitor 1310 and the second semiconductor die 1220 and the anode electrode is grounded. Also, when the capacitor 1310 is disposed on the second electrical path 1232, the diode 1320 may be disposed so that the cathode electrode is connected to the one electrode of the capacitor 1310 and the first semiconductor die 1210 and the anode electrode is grounded. When the first semiconductor die 1210 and the second semiconductor die 1220 transmit and receive data to and from each other through a single electrical path, the diode 1320 may be disposed in each of the one electrode and the other electrode of the capacitor 1310 disposed on the electrical path.

By including the capacitor chips 1300 coupled between the first semiconductor die 1210 and the second semiconductor die 1220, the semiconductor package 1000 according to one embodiment of the present disclosure can remove a DC component and allow only a radio frequency signal to pass in chip-to-chip communication between the first semiconductor die 1210 and the second semiconductor die 1220. Accordingly, by blocking common-mode noise in the chip-to-chip communication, the semiconductor package 1000 can improve electromagnetic interference (EMI) performance and signal integrity. Also, the semiconductor package 1000 can remove a DC offset and improve compatibility between the heterogeneous semiconductor dies.

Also, by including the capacitor chips 1300 on which the capacitor 1310 and the diode 1320 are integrated, the semiconductor package 1000 according to one embodiment of the present disclosure can prevent damage to the capacitor 1310, which is caused by a surge voltage flowing in the chip-to-chip communication line, through the diode 1320. As a plurality of chips and wirings are integrated at a high density in a semiconductor package, a surge signal may be generated in a chip-to-chip communication line due to electrical interference of an adjacent signal line. Also, in a communication line between heterogeneous chips having different driving voltages, a voltage peak corresponding to surge may be generated due to grounding imbalance or impedance mismatch. When the surge signal is applied to a coupling capacitor connected to the chip-to-chip communication line, dielectric breakdown of the capacitor may occur. On the other hand, by including the capacitor chips 1300 on which a coupling capacitor and an ESD protection diode are integrated, the semiconductor package 1000 according to one embodiment of the present disclosure allows the capacitor 1310 to be effectively protected from a surge signal of a chip-to-chip communication line by the diode 1320 while the capacitor 1310 performs AC coupling of heterogeneous chips.

Also, by including the capacitor chips 1300 on which the diode 1320 is disposed between a transmitter of a semiconductor die and the capacitor 1310, the semiconductor package 1000 according to one embodiment of the present disclosure can protect the capacitor 1310 from a surge signal that is introduced in a direction from a transmitter of a semiconductor die toward a receiver thereof.

Further, by including the capacitor chips 1300 on which the diode 1320 is disposed between a receiver of a semiconductor die and the capacitor 1310, the semiconductor package 1000 according to one embodiment of the present disclosure can protect the capacitor 1310 from a surge signal that returns in a direction from the receiver toward the transmitter due to impedance mismatch or high-speed signal reflection between heterogeneous chips.

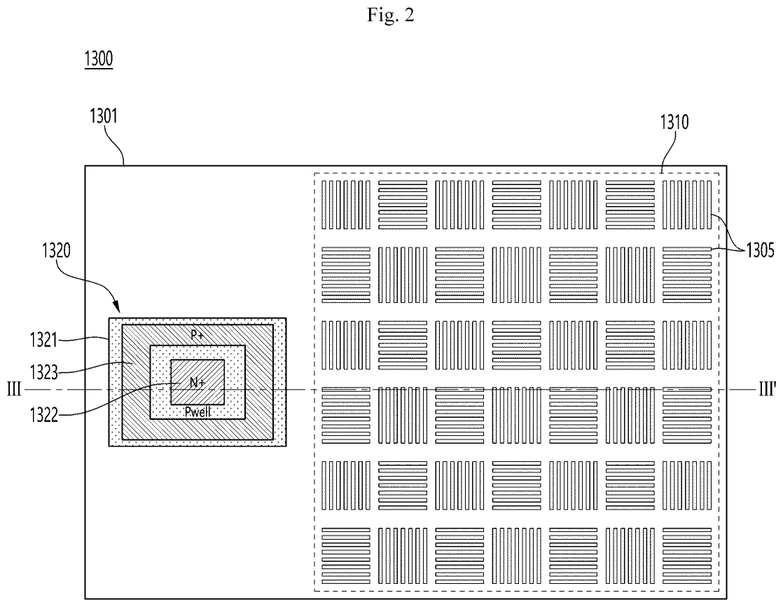

FIG. 2 is a schematic top view of a capacitor chip of FIG. 1.

Referring to FIG. 2, the capacitor chip 1300 according to the present embodiment may further include a substrate 1301, and the diode 1320 may include a well region 1321, a first doping region 1322, and a second doping region 1323.

Referring to FIG. 2, the substrate 1301 may include various materials. Specifically, the substrate 1301 may include a semiconductor material. For example, the substrate 1301 may include a semiconductor element such as silicon or germanium or a compound semiconductor such as SiC, GaAs, InAs, or InP. Preferably, the substrate 1301 may be a silicon substrate.

The substrate 1301 may be a separate substrate from the package substrate 1100 or the interposer (not illustrated). The substrate 1301 may be a substrate independent from the package substrate 1100 or the interposer and may be mounted on, attached to, or embedded in the package substrate 1100 or the interposer. In some cases, the substrate 1301 may be the same substrate as the package substrate 1100 or the interposer. That is, the substrate 1301 may be integrally formed with the package substrate 1100 or the interposer.

A plurality of first trenches 1305 may be formed at one side of the substrate 1301. The plurality of first trenches 1305 may be arranged in various forms on the substrate 1301. Specifically, the plurality of first trenches 1305 may include a plurality of horizontally extending first trenches 1305 and a plurality of vertically extending first trenches 1305 on a plane of the substrate 1301. For example, the plurality of first trenches 1305 may have a form in which a horizontal first trench unit that consists of the plurality of horizontally extending first trenches 1305 and a vertical first trench unit that consists of the plurality of vertically extending first trenches 1305 are alternately arranged on the plane of the substrate 1301.

Referring to FIG. 2, the capacitor 1310 may be disposed in the plurality of first trenches 1305. Specifically, the capacitor 1310 may be disposed on an upper surface of the substrate 1301 and in the plurality of first trenches 1305. That is, regions in which the plurality of first trenches 1305 are disposed may be regions in which the capacitor 1310 is disposed.

Referring to FIG. 2, the diode 1320 may include the well region 1321, the first doping region 1322, and the second doping region 1323. Specifically, the diode 1320 may include the well region 1321, the first doping region 1322 connected to the cathode electrode, and the second doping region 1323 connected to the anode electrode.

The diode 1320 may be an ESD protection diode. For example, the diode 1320 may be a diode including an N+/Pwell junction. Specifically, the diode 1320 may be a diode having an N+/Pwell/P+ junction.

The well region 1321 may be a partial region of the substrate 1301 that is formed by being doped with a selected impurity. For example, the well region 1321 may be a Pwell doped with a P-type impurity.

Referring to FIG. 2, the first doping region 1322 may be a region doped with a first impurity. Specifically, the first doping region 1322 may be a region in which a partial region of the well region 1321 is doped with the first impurity. The first impurity may include various impurities. For example, the first impurity may be an N-type impurity. That is, the first doping region 1322 may be an N+ region doped with the N-type impurity.

Referring to FIG. 2, the second doping region 1323 may be a region doped with a second impurity. Specifically, the second doping region 1323 may be a region in which a partial region of the well region 1321 is doped with the second impurity. The second impurity may include various impurities. Specifically, the second impurity may be a different type of impurity from the first impurity. More specifically, the second impurity may be a different type of impurity from the first impurity and may be the same impurity as the impurity with which the well region 1321 is doped. For example, the second impurity may be a P-type impurity. That is, the second doping region 1323 may be a P+ region doped with the P-type impurity.

The second doping region 1323 may be a high-concentration region in which the well region 1321 doped with the P-type impurity is additionally doped with the P-type impurity. Accordingly, a doping concentration of the second doping region 1323 may be higher than a doping concentration of the well region 1321.

Referring to FIG. 2, the second doping region 1323 may be disposed to be spaced from the first doping region 1322 in the well region 1321. Specifically, the second doping region 1323 may be disposed to be spaced from the first doping region 1322 to surround the first doping region 1322 in the well region 1321. The well region 1321 may be disposed between the first doping region 1322 and the second doping region 1323.

Referring to FIG. 2, at least one capacitor 1310 and at least one diode 1320 may be formed on a single substrate 1301. Specifically, the capacitor 1310 and the diode 1320 may be disposed at positions spaced from each other on the substrate 1301. For example, the diode 1320 may be disposed at a position spaced a predetermined distance from an edge of one side of the capacitor 1310.

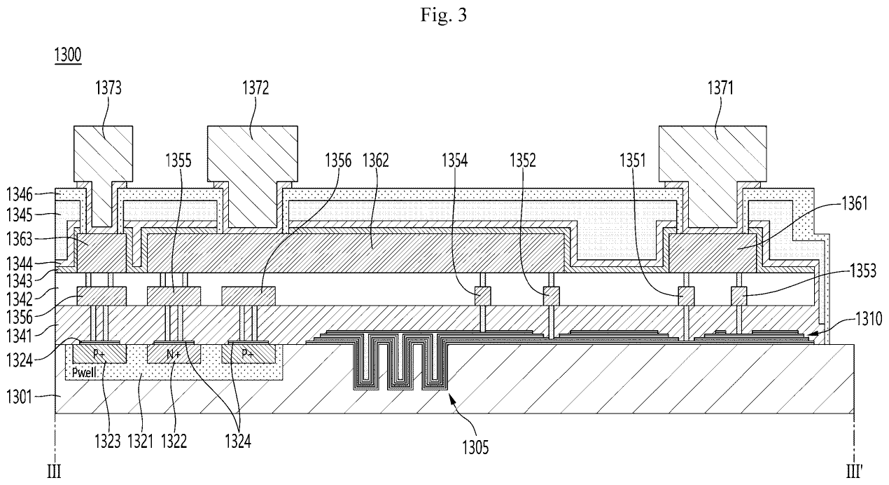

FIG. 3 is a schematic cross-sectional view of the capacitor chip of FIG. 2 along line III-III′ of FIG. 2.

Referring to FIG. 3, the capacitor chip 1300 according to the present embodiment may further include insulating layers 1341 to 1346, metal patterns 1351 to 1356 and 1361 to 1363, and pads 1371 to 1373.

Referring to FIG. 3, the capacitor 1310 may consist of a plurality of metal layers and dielectric layers disposed between the plurality of metal layers. Specifically, the capacitor 1310 may consist of a plurality of metal layers sequentially stacked on the upper surface of the substrate 1301 and in the first trenches 1305 and dielectric layers disposed between the plurality of metal layers. For example, the capacitor 1310 may include a first metal layer disposed on the upper surface of the substrate 1301, a second metal layer disposed on the first metal layer, a third metal layer disposed on the second metal layer, a fourth metal layer disposed on the third metal layer, a first dielectric layer disposed between the first metal layer and the second metal layer, a second dielectric layer disposed between the second metal layer and the third metal layer, and a third dielectric layer disposed between the third metal layer and the fourth metal layer.

Referring to FIG. 3, the first metal layer and the third metal layer may be electrically connected. For example, the first metal layer and the third metal layer may be electrically connected and may serve as a first electrode of the capacitor 1310. Also, the second metal layer and the fourth metal layer may be electrically connected. For example, the second metal layer and the fourth metal layer may be electrically connected and may serve as a second electrode of the capacitor 1310.

Referring to FIG. 3, the well region 1321 of the diode 1320 may be formed to be deeper than the first doping region 1322 and the second doping region 1323. Specifically, in terms of a depth formed in the vertical direction based on the upper surface of the substrate 1301, the depth of the well region 1321 may be larger than each of the depth of the first doping region 1322 and the depth of the second doping region 1323.

Referring to FIG. 3, an ohmic contact layer 1324 may be formed on an upper surface of the first doping region 1322 or the second doping region 1323. The ohmic contact layer 1324 may form ohmic contact between the first doping region 1322 or the second doping region 1323 and a metal. Also, the ohmic contact layer 1324 may serve as an etching stop layer that prevents damage to the first doping region 1322 or the second doping region 1323 in a process of etching an upper layer of the first doping region 1322 or the second doping region 1323.

The ohmic contact layer 1324 may include various conductive materials. For example, the ohmic contact layer 1324 may include Ti, TiN, Ni, Co, NiSi, TiSi₂, or WSiₓ. Preferably, the ohmic contact layer 1324 may consist of a Ti/TiN stacking structure.

Referring to FIG. 3, a first insulating layer 1341 may be disposed on the capacitor 1310 and the diode 1320. Specifically, the first insulating layer 1341 may be disposed to entirely cover upper surfaces of the capacitor 1310 and the diode 1320.

The first insulating layer 1341 may include various insulating materials. Specifically, the first insulating layer 1341 may include a silicon oxide, a silicon nitride, or a low-permittivity material. For example, the first insulating layer 1341 may include SiO₂, Si₃N₄, or SiOₓN_{y}.

Referring to FIG. 3, metal patterns 1351 to 1356 may be disposed on the first insulating layer 1341. For example, a first metal pattern 1351, a second metal pattern 1352, a third metal pattern 1353, a fourth metal pattern 1354, a fifth metal pattern 1355, or a sixth metal pattern 1356 may be disposed on an upper surface of the first insulating layer 1341.

The first to sixth metal patterns 1351 to 1356 may be disposed to be spaced from one another. Specifically, the first to fourth metal patterns 1351 to 1354 may be disposed to be spaced from one another on the upper surface of the first insulating layer 1341 to overlap the capacitor 1310 in a direction perpendicular to the plane of the substrate 1301. Also, the fifth metal pattern 1355 and the sixth metal pattern 1356 may be disposed to be spaced from each other on the upper surface of the first insulating layer 1341 to overlap the diode 1320 in the direction perpendicular to the plane of the substrate 1301. In some cases, the first metal pattern 1351 and the third metal pattern 1353 may be integrally formed, or the second metal pattern 1352 and the fourth metal pattern 1354 may be integrally formed.

Referring to FIG. 3, first vias may be disposed between the first to fourth metal patterns 1351 to 1354 and the capacitor 1310 or between the fifth and sixth metal patterns 1355 and 1356 and the diode 1320. For example, the first via may be disposed between the first metal pattern 1351 and the first metal layer of the capacitor 1310, between the second metal pattern 1352 and the second metal layer of the capacitor 1310, between the third metal pattern 1353 and the third metal layer of the capacitor 1310, between the fourth metal pattern 1354 and the fourth metal layer of the capacitor 1310, between the fifth metal pattern 1355 and the first doping region 1322, or between the sixth metal pattern 1356 and the second doping region 1323. In some cases, the first via may be disposed between the fifth metal pattern 1355 and the ohmic contact layer 1324 on the first doping region 1322 or between the sixth metal pattern 1356 and the ohmic contact layer 1324 on the second doping region 1323. Accordingly, the ohmic contact layer 1324 can prevent damage to the first doping region 1322 or the second doping region 1323 that may occur in a via formation process.

The first via may include a conductive material. The first via may be a conductive via and may electrically connect the first to fourth metal patterns 1351 to 1354 and the capacitor 1310 and electrically connect the fifth and sixth metal patterns 1355 and 1356 and the diode 1320.

Referring to FIG. 3, the fifth metal pattern 1355 may be a cathode electrode of the diode 1320. Specifically, the fifth metal pattern 1355 may serve as the cathode electrode of the diode 1320 by being electrically connected to the ohmic contact layer 1324 disposed on the first doping region 1322 or the upper surface of the first doping region 1322. Also, the sixth metal pattern 1356 may be an anode electrode of the diode 1320. Specifically, the sixth metal pattern 1356 may serve as the anode electrode of the diode 1320 by being electrically connected to the ohmic contact layer 1324 disposed on the second doping region 1323 or the upper surface of the second doping region 1323.

Referring to FIG. 3, a second insulating layer 1342 may be disposed on the first to sixth metal patterns 1351 to 1356. Specifically, the second insulating layer 1342 may be disposed to cover the first to sixth metal patterns 1351 to 1356 on the first insulating layer 1341. The second insulating layer 1342 may be substantially the same insulating layer as the first insulating layer 1341.

Referring to FIG. 3, seventh to ninth metal patterns 1361 to 1363 may be disposed on the second insulating layer 1342. Specifically, a seventh metal pattern 1361, an eighth metal pattern 1362, and a ninth metal pattern 1363 may be disposed on an upper surface of the second insulating layer 1342.

The seventh to ninth metal patterns 1361 to 1363 may be disposed to be spaced from one another. For example, in the direction perpendicular to the plane of the substrate 1301, the seventh to ninth metal patterns 1361 to 1363 may be disposed to be spaced from one another so that at least a portion of the seventh metal pattern 1361 overlaps the first metal pattern 1351 or the third metal pattern 1353, at least a portion of the eighth metal pattern 1362 overlaps the second metal pattern 1352, the fourth metal pattern 1354, or the fifth metal pattern 1355, and at least a portion of the ninth metal pattern 1363 overlaps the sixth metal pattern 1356.

Referring to FIG. 3, second vias may be disposed between the first to sixth metal patterns 1351 to 1356 and the seventh to ninth metal patterns 1361 to 1363. For example, the second via may be disposed between the seventh metal pattern 1361 and the first metal pattern 1351, between the seventh metal pattern 1361 and the third metal pattern 1353, between the eighth metal pattern 1362 and the second metal pattern 1352, between the eighth metal pattern 1362 and the fourth metal pattern 1354, between the eighth metal pattern 1362 and the fifth metal pattern 1355, or between the ninth metal pattern 1363 and the sixth metal pattern 1356. The second via may be formed of substantially the same material as the first via.

Referring to FIG. 3, the seventh metal pattern 1361 may electrically connect the first metal pattern 1351 and the third metal pattern 1353 through the second via. Specifically, the seventh metal pattern 1361 may electrically connect the first metal pattern 1351 and the third metal pattern 1353 through the second via and may electrically connect the first metal layer and the third metal layer of the capacitor 1310 through the first via. That is, the first metal layer and the third metal layer of the capacitor 1310 may constitute one electrode of the capacitor 1310 by being electrically connected through the first via, the first metal pattern 1351, the third metal pattern 1353, the second via, and the seventh metal pattern 1361.

Referring to FIG. 3, the eighth metal pattern 1362 may electrically connect the second metal pattern 1352, the fourth metal pattern 1354, or the fifth metal pattern 1355 through the second via. Specifically, the eighth metal pattern 1362 may electrically connect the second metal pattern 1352 and the fourth metal pattern 1354 through the second via and may electrically connect the second metal layer and the fourth metal layer of the capacitor 1310 through the first via. That is, the second metal layer and the fourth metal layer of the capacitor 1310 may constitute one electrode of the capacitor 1310 by being electrically connected through the first via, the second metal pattern 1352, the fourth metal pattern 1354, the second via, and the eighth metal pattern 1362. Also, the eighth metal pattern 1362 may electrically connect the second metal pattern 1352, the fourth metal pattern 1354, and the fifth metal pattern 1355 through the second via and may electrically connect the second metal layer and the fourth metal layer of the capacitor 1310 and the first doping region 1322 of the diode 1320 through the first via. That is, the one electrode that the second metal layer and the fourth metal layer of the capacitor 1310 constitute and the first doping region 1322 of the diode 1320 may be electrically connected through the first via, the second metal pattern 1352, the fourth metal pattern 1354, the fifth metal pattern 1355, the second via, and the eighth metal pattern 1362.

Referring to FIG. 3, the ninth metal pattern 1363 may be electrically connected to the sixth metal pattern 1356 through the second via. The ninth metal pattern 1363 may serve as the anode electrode of the diode 1320 by being electrically connected to the ohmic contact layer 1324 disposed on the second doping region 1323 or the upper surface of the second doping region 1323 through the second via, the sixth metal pattern 1356, and the first via.

Referring to FIG. 3, a third insulating layer 1343 may be disposed on the seventh to ninth metal patterns 1361 to 1363. Specifically, the third insulating layer 1343 may be disposed to cover the seventh metal pattern 1361, the eighth metal pattern 1362, and the ninth metal pattern 1363 on the second insulating layer 1342.

The third insulating layer 1343 may include various insulating materials. Specifically, the third insulating layer 1343 may include an inorganic insulating material. For example, the third insulating layer 1343 may include SiO₂, Si₃N₄, or SiOₓN_{y}. In some cases, the third insulating layer 1343 may include a low-permittivity material.

Referring to FIG. 3, a fourth insulating layer 1344 may be disposed on the third insulating layer 1343. Specifically, the fourth insulating layer 1344 may be disposed to cover an upper surface of the third insulating layer 1343.

The fourth insulating layer 1344 may include various insulating materials. Specifically, the fourth insulating layer 1344 may include an inorganic insulating material or a low-permittivity material. More specifically, the fourth insulating layer 1344 may include a different inorganic insulating material from the third insulating layer 1343. For example, the fourth insulating layer 1344 may include SiO₂, Si₃N₄, or SiOₓN_{y}.

Referring to FIG. 3, a fifth insulating layer 1345 may be disposed on the fourth insulating layer 1344. Specifically, the fifth insulating layer 1345 may be disposed to cover an upper surface of the fourth insulating layer 1344.

The fifth insulating layer 1345 may include an organic insulating material or a low-permittivity material. For example, the fifth insulating layer 1345 may include polyimide (PI), benzocyclobutene (BCB), spin-on-glass (SOG), or SiOC.

Referring to FIG. 3, a sixth insulating layer 1346 may be disposed on the fifth insulating layer 1345. Specifically, the sixth insulating layer 1346 may be disposed to cover an upper surface of the fifth insulating layer 1345.

The sixth insulating layer 1346 may be a passivation layer. For example, the sixth insulating layer 1346 may include Si₃N₄, SiO₂, SiON, Al₂O₃, PI, BCB, SOG, or SiOC.

Referring to FIG. 3, the pads 1371, 1372, and 1373 may be disposed on the sixth insulating layer 1346. Specifically, the pads 1371, 1372, and 1373 may be disposed to be spaced from one another on an upper surface of the sixth insulating layer 1346. More specifically, in the direction perpendicular to the plane of the substrate 1301, a first pad 1371, a second pad 1372, and a third pad 1373 may be disposed to be spaced from one another so that at least a partial region of the first pad 1371 overlaps the seventh metal pattern 1361, at least a partial region of the second pad 1372 overlaps the eighth metal pattern 1362, and at least a partial region of the third pad 1373 overlaps the ninth metal pattern 1363.

The pads 1371, 1372, and 1373 may be connected to the metal patterns 1351 to 1356 and 1361 to 1363. Specifically, the pads 1371, 1372, and 1373 may pass through the plurality of insulating layers 1343, 1344, 1345, and 1346 and may be directly connected to the metal patterns 1351 to 1356 and 1361 to 1363. For example, the first pad 1371 may be directly connected to the seventh metal pattern 1361, the second pad 1372 may be directly connected to the eighth metal pattern 1362, and the third pad 1373 may be directly connected to the ninth metal pattern 1363. As a result, by the second pad 1372 being connected to the eighth metal pattern 1362, the cathode electrode that corresponds to the first doping region 1322 of the diode 1320 and one electrode of the capacitor 1310 can be connected with a single node.

By including the capacitor chips 1300 in which the capacitor 1310 and the diode 1320 are formed on a single substrate 1301, the semiconductor package 1000 according to one embodiment of the present disclosure can reduce an area of the package substrate 1100 that is occupied by the capacitor 1310 and the diode 1320 and can simplify a package assembly process. Accordingly, the semiconductor package 1000 can ease layout limitations in the package assembly process and reduce manufacturing costs.

Also, by including the capacitor chips 1300 in which the capacitor 1310 and the diode 1320 are integrated on the same substrate 1301, the semiconductor package 1000 according to one embodiment of the present disclosure can prevent problems of an increase in process complexity, an increase in contact resistance, and impedance mismatch that may occur when the capacitor 1310 and the diode 1320 are separately connected on the package substrate 1100. Accordingly, the semiconductor package 1000 can secure signal integrity and operation stability of chip-to-chip communication by improving electrical performance and reliability of the capacitor chips 1300 performing a coupling function between semiconductor dies.

Further, by including the capacitor chips 1300 formed by one electrode of the capacitor 1310 and the cathode electrode of the diode 1320 being connected, the semiconductor package 1000 according to one embodiment of the present disclosure allows a surge voltage introduced into the capacitor 1310 to be effectively released through the diode 1320. Accordingly, the semiconductor package 1000 can improve stability and signal integrity of chip-to-chip communication by preventing dielectric breakdown of the capacitor 1310 caused by the surge voltage.

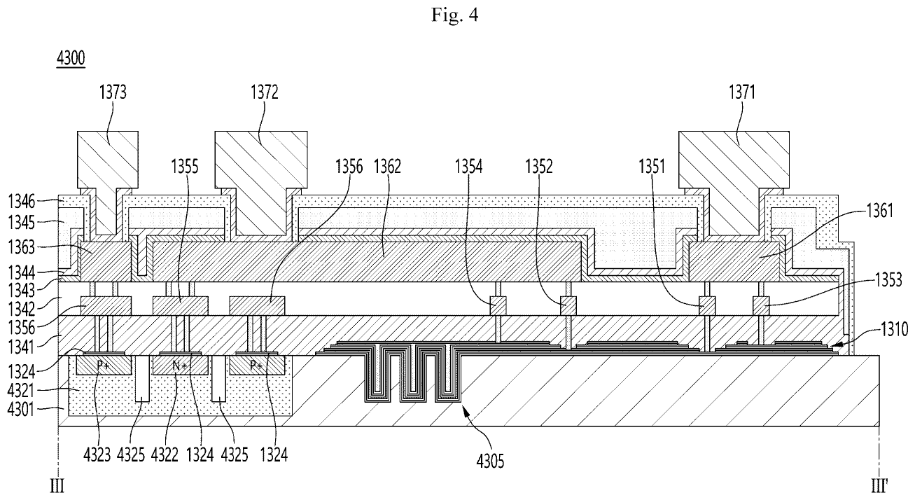

FIG. 4 is a cross-sectional view of the capacitor chip of FIG. 2 along line III-III′ of FIG. 2 according to another embodiment.

Referring to FIG. 4, a capacitor chip 4300 according to the present embodiment may further include a second trench 4325 formed between a first doping region 4322 and a second doping region 4323 in addition to the configuration of the capacitor chip 1300 of FIGS. 1 to 3. Accordingly, repeated description of substantially the same configuration as the capacitor chip 1300 of FIGS. 1 to 3 will be omitted.

Referring to FIG. 4, the second trench 4325 may be disposed between the first doping region 4322 and the second doping region 4323 in a well region 4321. For example, the second trench 4325 may be disposed to surround the first doping region 4322 along an edge of the first doping region 4322.

The second trench 4325 may be formed to be deeper than the first doping region 4322 and the second doping region 4323. Specifically, in terms of a depth formed in the vertical direction based on an upper surface of a substrate 4301, the depth of the second trench 4325 may be larger than or equal to each of the depth of the first doping region 4322 and the depth of the second doping region 4323 and may be smaller than the depth of the well region 4321.

In some cases, the depth of the second trench 4325 may be equal to the depth of a first trench 4305 of the capacitor 1310. The first trench 4305 and the second trench 4325 may have the same size and shape due to being formed with the same process. Accordingly, problems of surface leakage current and parasitic bipolar junction transistor (BJT) formation that may occur between the first doping region 4322 and the second doping region 4323 can be prevented. The first trench 4305 may be substantially the same as the first trench 1305 of FIGS. 2 and 3.

According to various embodiments of the present disclosure, the second trench 4325 may be filled with an insulating material. Specifically, the second trench 4325 may be filled with an inorganic insulating layer, an organic insulating layer, or a low-permittivity insulating material. For example, the second trench 4325 may be filled with SiO₂, Si₃N₄, or SiON. Accordingly, because electrical insulation between the first doping region 4322 and the second doping region 4323 is strengthened by the second trench 4325, the possibility of occurrence of surface leakage current and parasitic BJT formation can be further reduced significantly.

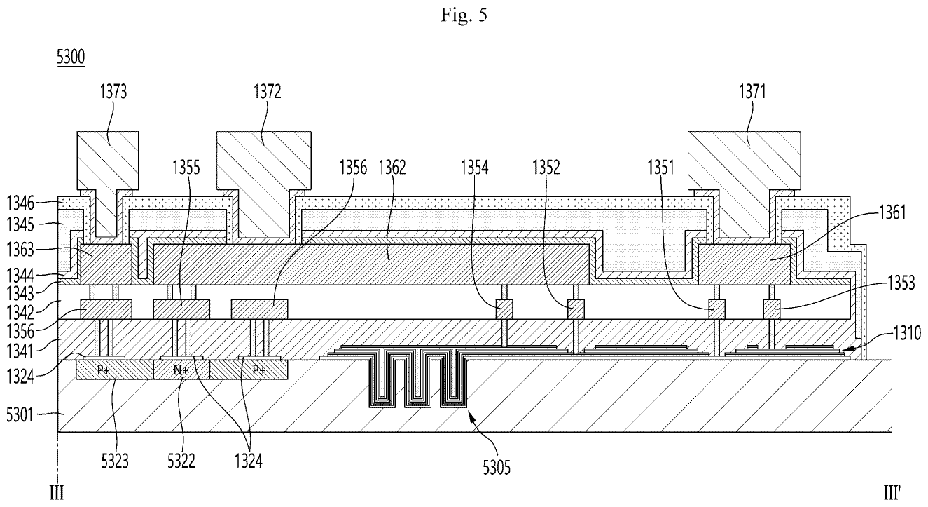

FIG. 5 is a cross-sectional view of the capacitor chip of FIG. 2 along line III-III′ of FIG. 2 according to still another embodiment.

Referring to FIG. 5, a capacitor chip 5300 according to the present embodiment may be different from the capacitor chip 1300 of FIGS. 1 to 3 in that a diode 5320 is configured as a Zener diode. Accordingly, repeated description of substantially the same configuration as the capacitor chip 1300 of FIGS. 1 to 3 will be omitted.

Referring to FIG. 5, the diode 5320 may be an ESD protection diode configured as a Zener diode. Specifically, the diode 5320 may discharge overvoltage or overcurrent introduced into a capacitor 5310 using Zener breakdown. For example, the diode 5320 may be a Zener diode with a breakdown voltage of 5 V or lower, and when an overvoltage of 5 V or higher is applied to the capacitor 5310, the diode 5320 may bypass or release the corresponding overvoltage. Accordingly, the diode 5320 can prevent dielectric breakdown of the capacitor 5310 and improve reliability of the semiconductor package. That is, by using a Zener diode even for a capacitor with a low breakdown voltage, dielectric breakdown of a coupling capacitor can be suppressed, and reliability of a semiconductor package can be improved.

Referring to FIG. 5, a first doping region 5322 and a second doping region 5323 may be disposed to be in contact. Specifically, the second doping region 5323 may be disposed in contact with the first doping region 5322 to surround the first doping region 5322.

By including the capacitor chip 5300 in which the capacitor 5310 and the Zener diode 5320 are formed on a single substrate 5301, a semiconductor package 5000 according to one embodiment of the present disclosure can continuously protect the capacitor 5310 without the diode 5320 being destroyed even when ESD has occurred. In particular, even when an abnormal voltage of 5 V or lower is instantaneously generated, in addition to when ESD has occurred, the capacitor 5310 and the semiconductor package 5000 including the same can be normally protected through the Zener diode 5320.

Also, by including the capacitor chip 5300 in which the capacitor 5310 and the Zener diode 5320 are formed on a single substrate 5301, the semiconductor package 5000 according to one embodiment of the present disclosure can implement the Zener diode 5320 just by junction between an N+ region and a P+ region. Accordingly, because a separate Pwell formation process is omitted, the semiconductor package 5000 can simplify the manufacturing process and reduce manufacturing costs and process time.

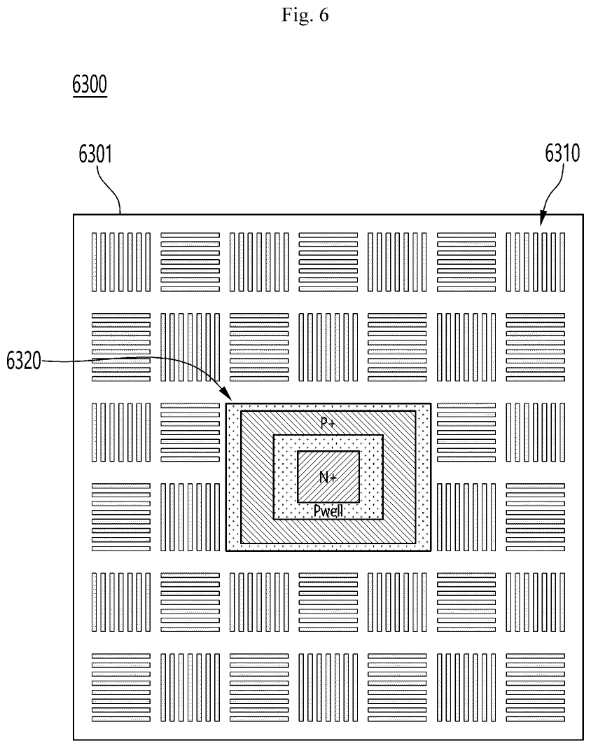

FIG. 6 is a schematic top view of a capacitor chip on which a diode is disposed to be surrounded by a trench capacitor according to another embodiment of the present disclosure.

Referring to FIG. 6, a capacitor chip 6300 according to the present embodiment may be different from the capacitor chip 1300 of FIGS. 1 to 3 in that a diode 6320 is configured to be surrounded by a capacitor 6310. Accordingly, repeated description of substantially the same configuration as the capacitor chip 1300 of FIGS. 1 to 3 will be omitted.

Referring to FIG. 6, at least one diode 6320 may be disposed in at least one capacitor 6310. Specifically, in the planar direction of a substrate 6301, the capacitor 6310 may be disposed to surround the diode 6320. More specifically, the capacitor 6310 may be disposed to be spaced from the diode 6320 to surround the diode 6320.

Referring to FIG. 6, the diode 6320 may be substantially the same diode as the diode 1320 of FIGS. 1 to 3. That is, the diode 6320 may be a diode having N+/Pwell/P+ junction. In some cases, the diode 6320 may be a Zener diode.

By including the capacitor chip 6300 on which the capacitor 6310 is disposed to surround the diode 6320, a semiconductor package 6000 according to one embodiment of the present disclosure can shield electromagnetic interference (EMI) that may occur when high-speed or high-voltage pulse current is discharged in the diode 6320.

Also, by including the capacitor chip 6300 on which the diode 6320 is disposed at the center of the capacitor 6310, the semiconductor package 6000 according to one embodiment of the present disclosure allows a discharge path to the diode 6320 to be configured to be symmetrical and short. Accordingly, the semiconductor package 6000 can improve a discharge response speed and the ESD protection characteristic.

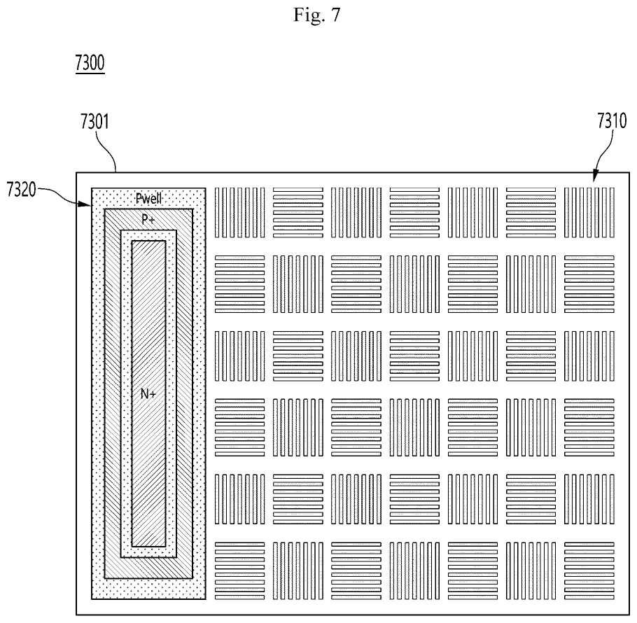

FIG. 7 is a schematic top view of a capacitor chip on which a diode is disposed along an edge of one side of a trench capacitor according to still another embodiment of the present disclosure.

Referring to FIG. 7, a capacitor chip 7300 according to the present embodiment may be different from the capacitor chip 1300 of FIGS. 1 to 3 in that a diode 7320 is configured to be disposed along an edge of one side of a capacitor 7310. Accordingly, repeated description of substantially the same configuration as the capacitor chip 1300 of FIGS. 1 to 3 will be omitted.

Referring to FIG. 7, at least one diode 7320 may be disposed at one side of at least one capacitor 7310. Specifically, at one side of at least one capacitor 7310, the diode 7320 may be disposed along an edge of the corresponding capacitor 7310. For example, in the planar direction of a substrate 7301, the diode 7320 may be disposed to extend in an up-down direction at a left side of the capacitor 7310. In some cases, one side of the capacitor 7310 at which the diode 7320 is disposed may be outward from the capacitor chip 7300.

Referring to FIG. 7, the diode 7320 may be substantially the same diode as the diode 1320 of FIGS. 1 to 3. That is, the diode 7320 may be a diode having N+/Pwell/P+ junction. In some cases, the diode 7320 may be a Zener diode.

By including the capacitor chip 7300 on which the diode 7320 is disposed along an edge of one side of the capacitor 7310, a semiconductor package 7000 according to one embodiment of the present disclosure can effectively block spike voltage or overvoltage, which may be introduced from outside the capacitor chip 7300, at the edge. Accordingly, by preventing overvoltage from being directly applied to the capacitor 7310, the semiconductor package 7000 can suppress dielectric breakdown of the capacitor 7310 and improve reliability.

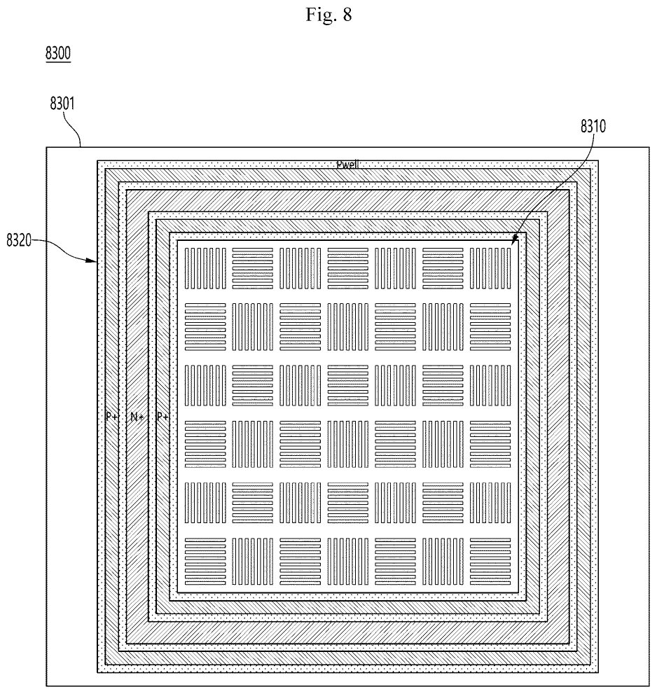

FIG. 8 is a schematic top view of a capacitor chip on which a diode is disposed to surround a trench capacitor according to yet another embodiment of the present disclosure.

Referring to FIG. 8, a capacitor chip 8300 according to the present embodiment may be different from the capacitor chip 1300 of FIGS. 1 to 3 in that a diode 8320 is configured to surround a capacitor 8310. Accordingly, repeated description of substantially the same configuration as the capacitor chip 1300 of FIGS. 1 to 3 will be omitted.

Referring to FIG. 8, at least one diode 8320 may be disposed to surround at least one capacitor 8310. Specifically, in the planar direction of a substrate 8301, the diode 8320 may be disposed to be spaced from the capacitor 8310 to surround the capacitor 8310.

Referring to FIG. 8, the diode 8320 may be substantially the same diode as the diode 1320 of FIGS. 1 to 3. That is, the diode 8320 may be a diode having N+/Pwell/P+ junction. In some cases, the diode 8320 may be a Zener diode.

By including the capacitor chip 8300 on which the diode 8320 is disposed to surround the capacitor 8310, a semiconductor package 8000 according to one embodiment of the present disclosure can more effectively block spike voltage or overvoltage, which may be introduced into the capacitor 8310 from the outside, at the diode 8320.

Also, by including the capacitor chip 8300 on which the diode 8320 is disposed to surround the capacitor 8310, a semiconductor package 8000 according to one embodiment of the present disclosure can prevent overvoltage from being directly introduced into the capacitor 8310 and discharge the corresponding overvoltage along the shortest path through the diode 8320, regardless of a direction of wiring or a direction in which the overvoltage is introduced. Accordingly, the semiconductor package 8000 can more stably suppress dielectric breakdown of the capacitor 8310 and improve the ESD protection characteristic and reliability.

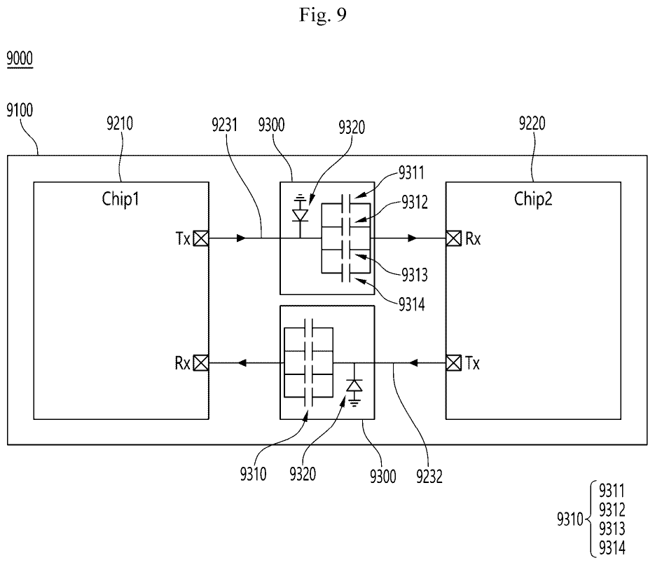

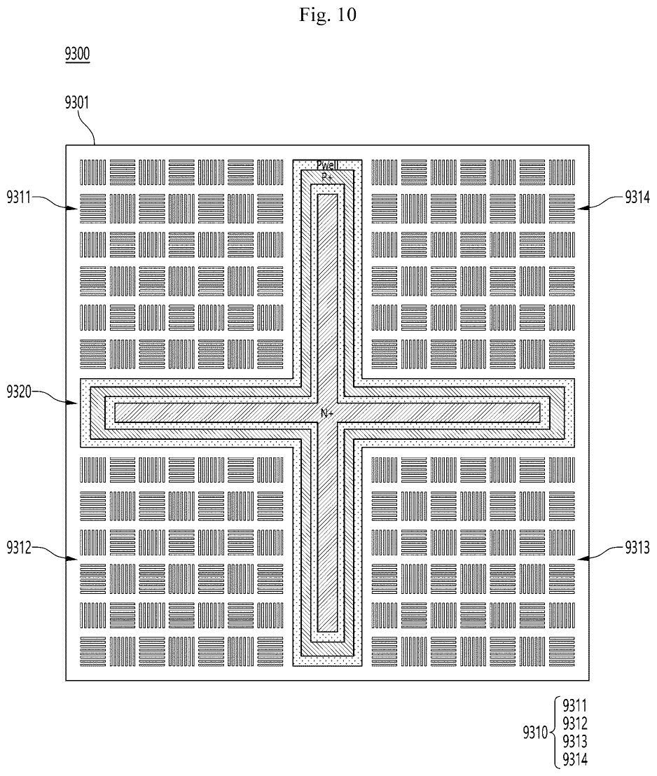

FIG. 9 is a top view of a semiconductor package according to another embodiment of the present disclosure. FIG. 10 is a schematic top view of a capacitor chip of FIG. 9.

Referring to FIGS. 9 and 10, a semiconductor package 9000 according to the present embodiment may further include a plurality of capacitors 9310 that are connected in parallel in addition to the configuration of the semiconductor package 1000 of FIGS. 1 to 3 and may be configured so that a diode 9320 is disposed between the plurality of capacitors 9310. Accordingly, repeated description of substantially the same configuration as the semiconductor package 1000 of FIGS. 1 to 3 will be omitted.

Referring to FIGS. 9 and 10, a plurality of capacitors 9310 may be disposed on a single capacitor chip 9300. Specifically, a plurality of capacitors 9310 formed on a single substrate 9301 may be disposed on the capacitor chip 9300. For example, a first capacitor 9311, a second capacitor 9312, a third capacitor 9313, and a fourth capacitor 9314 may be disposed on the substrate 9301 of the capacitor chip 9300.

The plurality of capacitors 9310 may be electrically connected to one another. Specifically, the plurality of capacitors 9310 may be connected in parallel. For example, one electrode of each of the plurality of capacitors 9310 may be connected to a first semiconductor die 9210, and the other electrode of each of the plurality of capacitors 9310 may be connected to a second semiconductor die 9220. More specifically, the plurality of capacitors 9310 may be connected in parallel in the capacitor chip 9300. That is, the plurality of capacitors 9310 may be connected in parallel through wiring formed in the capacitor chip 9300. In some cases, at least one electrode of each of the plurality of capacitors 9310 may be electrically connected outside the capacitor chip 9300. Specifically, at least one electrode of each of the plurality of capacitors 9310 may be electrically connected on electrical paths 9231 and 9232 between the plurality of capacitors 9310 and the semiconductor dies 9210 and 9220 or may be electrically connected in the semiconductor dies 9210 and 9220.

The number of the plurality of capacitors 9310 connected in parallel may be determined according to a frequency of a chip-to-chip communication signal between the first semiconductor die 9210 and the second semiconductor die 9220. Specifically, the number of the plurality of capacitors 9310 connected in parallel may be determined so that an optimal equivalent capacitance can be placed according to the frequency of the chip-to-chip communication signal between the first semiconductor die 9210 and the second semiconductor die 9220.

Each of the plurality of capacitors 9310 may be substantially the same capacitor as the capacitor 1310 of FIGS. 1 to 3. Specifically, each of the plurality of capacitors 9310 may be the same type as the capacitor 1310 of FIGS. 1 to 3 and may have the same size and capacitance as the capacitor 1310 of FIGS. 1 to 3.

According to various embodiments of the present disclosure, the plurality of capacitors 9310 may have different capacitances. For example, the first capacitor 9311 may have the highest capacitance among the plurality of capacitors 9310, the second capacitor 9312 may have a lower capacitance than the first capacitor 9311, the third capacitor 9313 may have a lower capacitance than the second capacitor 9312, and the fourth capacitor 9314 may have a lower capacitance than the third capacitor 9313.

On the plane of the substrate 9301, the first capacitor 9311 may have the largest planar area among the plurality of capacitors 9310, and the second capacitor 9312, the third capacitor 9313, and the fourth capacitor 9314 may have gradually decreasing planar areas. Also, the sum of the planar area of the first capacitor 9311 and the planar area of the fourth capacitor 9314 may be equal to the sum of the planar area of the second capacitor 9312 and the planar area of the third capacitor 9313. Therefore, even when the capacitances of the plurality of capacitors 9310 become different from one another, the capacitor chip 9300 can maintain the same size and planar area. Accordingly, the semiconductor package 9000 according to one embodiment of the present disclosure can reduce manufacturing costs and process time of the capacitor chip 9300 including the plurality of capacitors 9310 having different capacitances.

Referring to FIG. 9, the diode 9320 may be connected to one side of the plurality of capacitors 9310 connected in parallel. Specifically, a single diode 9320 may be connected to a single node to which one electrode of each of the plurality of capacitors 9310 connected in parallel is connected. For example, the plurality of capacitors 9310 may be connected in parallel through wiring formed in the capacitor chip 9300, and a single diode 9320 may be connected to a single node to which one electrode of each of the plurality of capacitors 9310 connected in parallel is connected. In some cases, a plurality of diodes 9320 may each be disposed at one electrode of one of the plurality of capacitors 9310. For example, different diodes 9320 may be connected to the first capacitor 9311, the second capacitor 9312, the third capacitor 9313, and the fourth capacitor 9314.

Referring to FIG. 10, the diode 9320 may be disposed between different pairs of the plurality of capacitors 9310. Specifically, the diode 9320 may be integrally disposed between different pairs of the plurality of capacitors 9310. For example, an integrated diode 9320 having a cross shape may be disposed between the first capacitor 9311 and the fourth capacitor 9314, between the second capacitor 9312 and the third capacitor 9313, between the first capacitor 9311 and the second capacitor 9312, and between the fourth capacitor 9314 and the third capacitor 9313.

According to various embodiments of the present disclosure, a plurality of switches (not illustrated) may be disposed between the plurality of capacitors 9310 connected in parallel and the first semiconductor die 9210 or between the plurality of capacitors 9310 connected in parallel and the second semiconductor die 9220. Specifically, the plurality of switches may be disposed in one of a region between the plurality of capacitors 9310 connected in parallel and the first semiconductor die 9210 and a region between the plurality of capacitors 9310 connected in parallel and the second semiconductor die 9220 where the diode 9320 is not disposed. For example, as disclosed in FIG. 9, when the diode 9320 is connected to a first electrical path 9231 between the plurality of capacitors 9310 and the first semiconductor die 9210, the switches may be disposed between the plurality of capacitors 9310 and the second semiconductor die 9220.

The plurality of switches may be disposed at various positions. Specifically, the plurality of switches may be disposed at various positions according to a position where electrodes of the plurality of capacitors 9310 are connected to one another. For example, when the electrodes of the plurality of capacitors 9310 are connected through wiring formed in the capacitor chip 9300, the plurality of switches may be disposed in the capacitor chip 9300. Also, when the electrodes of the plurality of capacitors 9310 are connected on the electrical paths 9231 and 9232 between the capacitor chip 9300 and the semiconductor dies 9210 and 9220, the plurality of switches may be disposed in the capacitor chip 9300 or on the electrical paths 9231 and 9232 between the capacitor chip 9300 and the semiconductor dies 9210 and 9220. When the electrodes of the plurality of capacitors 9310 are electrically connected in the semiconductor dies 9210 and 9220, the plurality of switches may be disposed in the capacitor chip 9300, on the electrical paths 9231 and 9232 between the capacitor chip 9300 and the semiconductor dies 9210 and 9220, or in the semiconductor dies 9210 and 9220.

By the plurality of switches being integrated in the capacitor chip 9300, the semiconductor package 9000 according to one embodiment of the present disclosure can reduce complexity of package wiring and simplify the package assembly process. Also, by including the switches disposed on the electrical paths 9231 and 9232 between the capacitor chip 9300 and the semiconductor dies 9210 and 9220, the semiconductor package 9000 according to one embodiment of the present disclosure allows a switch to be placed on an electrical path of each of the plurality of capacitors 9310 without changing the design of the capacitor chip 9300 and the semiconductor dies 9210 and 9220. Further, by including the switches disposed in the semiconductor dies 9210 and 9220, the semiconductor package 9000 according to one embodiment of the present disclosure can minimize a switch control signal path between the semiconductor dies 9210 and 9220 and the switch. Accordingly, by reducing resistance in the switch control signal path, the semiconductor package 9000 can secure high-speed response and high-speed signal quality of the switch.

The first semiconductor die 9210 and the second semiconductor die 9220 may control on/off of each of the plurality of switches. Accordingly, by controlling the switches in real time according to a frequency of a transmission signal, the first semiconductor die 9210 and the second semiconductor die 9220 can adjust the equivalent capacitance of the chip-to-chip communication line in real time. Therefore, by adjusting the equivalent capacitance of the chip-to-chip communication line in real time according to the frequency of the transmission signal, the first semiconductor die 9210 and the second semiconductor die 9220 can minimize signal distortion according to a frequency band of the chip-to-chip communication signal and can maintain uniform signal quality across a wide bandwidth.

By including the capacitor chip 9300 that includes the plurality of capacitors 9310 connected in parallel, the semiconductor package 9000 according to one embodiment of the present disclosure can precisely implement an equivalent capacitance according to the frequency of a chip-to-chip communication signal. Also, even when an error occurs in the capacitance of the capacitor due to a manufacturing error, the semiconductor package 9000 can implement the equivalent capacitance to be more similar to a target capacitance due to the parallel combination.

Also, by including the AC-coupling capacitor chip 9300 in which the plurality of capacitors 9310 that are connected in parallel and have different capacitances are disposed, the semiconductor package 9000 according to one embodiment of the present disclosure allows each capacitor to operate with optimal signal transmission characteristics in various frequency bands. For example, by including a large-capacity capacitor for processing a low-frequency signal, an intermediate-capacity capacitor for processing an intermediate-frequency signal, and a small-capacity capacitor for processing a high-frequency signal, the semiconductor package 9000 can use a suitable capacitor path for all of various frequency bands of chip-to-chip communication and can maintain optimal signal quality.

Also, by including the first semiconductor die 9210 and the second semiconductor die 9220 that use switches to control connection of each of the capacitors 9310 connected in parallel, the semiconductor package 9000 according to one embodiment of the present disclosure can finely adjust the equivalent capacitance of each chip-to-chip communication line in real time. Accordingly, the semiconductor package 9000 can minimize signal distortion according to a frequency band of the chip-to-chip communication signal and can maintain uniform signal quality across a wide bandwidth.

Also, by including the coupling capacitor chip 9300 in which the plurality of capacitors 9310 having different capacitances are disposed and the semiconductor dies 9210 and 9220 that use switches to control connection of each of the capacitors 9310 connected in parallel, the semiconductor package 9000 according to one embodiment of the present disclosure can more finely adjust the equivalent capacitance of each chip-to-chip communication line.

Further, by including the capacitor chip 9300 in which a single diode 9320 is disposed between the plurality of capacitors 9310, the semiconductor package 9000 according to one embodiment of the present disclosure can protect the plurality of capacitors 9310 with only one diode 9320. Accordingly, by protecting the plurality of capacitors 9310 with one diode 9320, the semiconductor package 9000 can simplify the design and manufacturing process of the capacitor chip 9300.

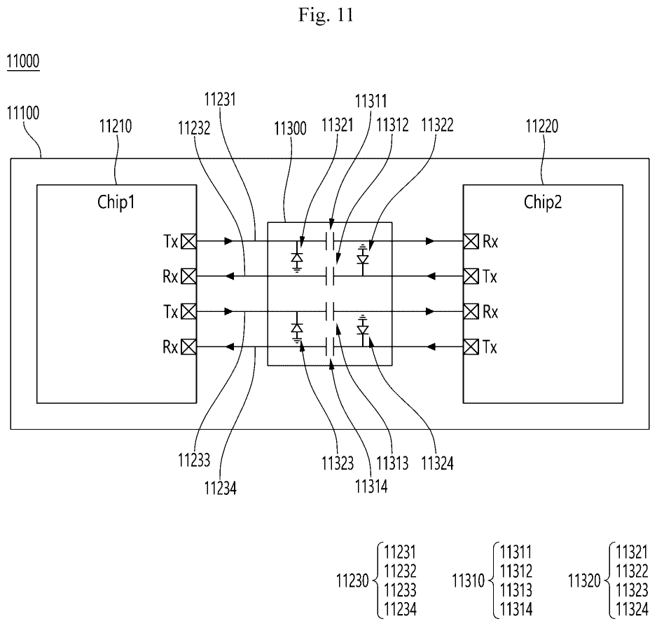

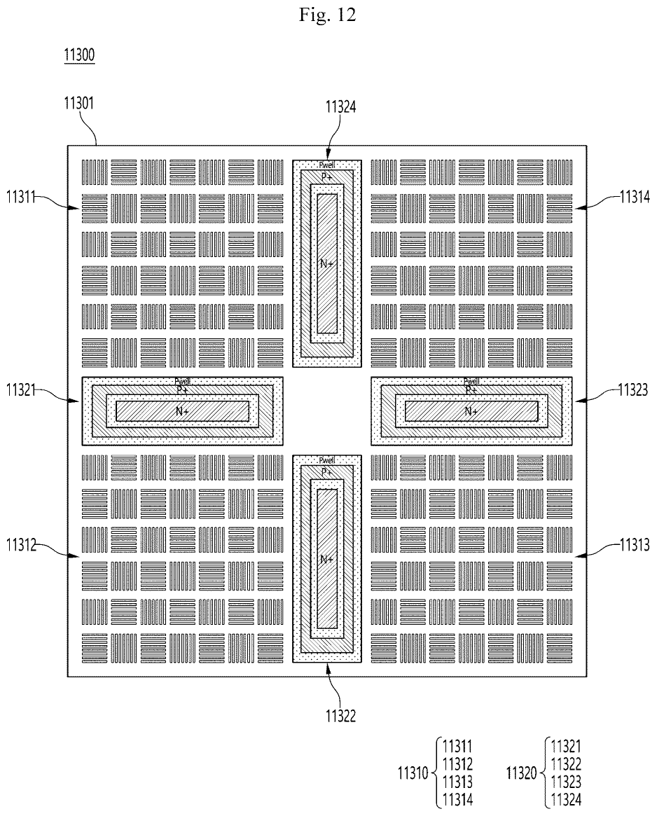

FIG. 11 is a top view of a semiconductor package according to still another embodiment of the present disclosure. FIG. 12 is a schematic top view of a capacitor chip of FIG. 11.

Referring to FIGS. 11 and 12, a semiconductor package 11000 according to the present embodiment may be different from the semiconductor package 1000 of FIGS. 1 to 3 in that a plurality of electrical paths 11231, 11232, 11233, and 11234 are configured to be connected to a single capacitor chip 11300. Accordingly, repeated description of substantially the same configuration as the semiconductor package 1000 of FIGS. 1 to 3 will be omitted.

Referring to FIGS. 11 and 12, a plurality of capacitors 11310 may be disposed in the single capacitor chip 11300. Specifically, the plurality of capacitors 11310 formed on a single substrate 11301 may be disposed in the capacitor chip 11300. For example, a first capacitor 11311, a second capacitor 11312, a third capacitor 11313, and a fourth capacitor 11314 may be disposed on the substrate 11301 of the capacitor chip 11300.

Each of the plurality of capacitors 11310 may be substantially the same capacitor as the capacitor 1310 of FIGS. 1 to 3. Specifically, each of the plurality of capacitors 11310 may be the same type as the capacitor 1310 of FIGS. 1 to 3 and may have the same size and capacitance as the capacitor 1310 of FIGS. 1 to 3.

According to various embodiments of the present disclosure, the plurality of capacitors 11310 may have different capacitances. For example, the first capacitor 11311 may have the highest capacitance among the plurality of capacitors 11310, the second capacitor 11312 may have a lower capacitance than the first capacitor 11311, the third capacitor 11313 may have a lower capacitance than the second capacitor 11312, and the fourth capacitor 11314 may have a lower capacitance than the third capacitor 11313.

On the plane of the substrate 11301, the first capacitor 11311 may have the largest planar area among the plurality of capacitors 11310, and the second capacitor 11312, the third capacitor 11313, and the fourth capacitor 11314 may have gradually decreasing planar areas. Also, the sum of the planar area of the first capacitor 11311 and the planar area of the fourth capacitor 11314 may be equal to the sum of the planar area of the second capacitor 11312 and the planar area of the third capacitor 11313. Therefore, even when the capacitances of the plurality of capacitors 11310 become different from one another, the capacitor chip 11300 can maintain the same size and planar area. Accordingly, the semiconductor package 11000 according to one embodiment of the present disclosure can reduce manufacturing costs and process time of the capacitor chip 11300 including the plurality of capacitors 11310 having different capacitances.

Each of the plurality of capacitors 11310 may be electrically connected to a first semiconductor die 11210 and a second semiconductor die 11220. Specifically, each of the plurality of capacitors 11310 may be connected to the first semiconductor die 11210 and the second semiconductor die 11220 through different electrical paths 11230. For example, the first capacitor 11311 may be connected to the first semiconductor die 11210 and the second semiconductor die 11220 through a first electrical path 11231, the second capacitor 11312 may be connected to the first semiconductor die 11210 and the second semiconductor die 11220 through a second electrical path 11232, the third capacitor 11313 may be connected to the first semiconductor die 11210 and the second semiconductor die 11220 through a third electrical path 11233, and the fourth capacitor 11314 may be connected to the first semiconductor die 11210 and the second semiconductor die 11220 through a fourth electrical path 11234. Each of the electrical paths 11230 may be substantially the same as the first electrical path 1231 or the second electrical path 1232 of FIG. 1.

Referring to FIG. 11, a plurality of diodes 11320 may be disposed to be connected to each of the plurality of capacitors 11310. Specifically, the plurality of diodes 11320 may be disposed to be connected to one electrode or the other electrode of each of the plurality of capacitors 11310. For example, a first diode 11321 may be disposed to be connected to one side of the first capacitor 11311, a second diode 11322 may be disposed to be connected to the other side of the second capacitor 11312, a third diode 11323 may be disposed to be connected to one side of the third capacitor 11313, and a fourth diode 11324 may be disposed to be connected to the other side of the fourth capacitor 11314.

Referring to FIG. 12, the plurality of diodes 11320 may be disposed between different pairs of the plurality of capacitors 11310. Specifically, the plurality of diodes 11320 may be disposed to be spaced from one another while disposed between different pairs of the plurality of capacitors 11310. For example, the first diode 11321 may be disposed between the first capacitor 11311 and the second capacitor 11312, the second diode 11322 may be disposed between the second capacitor 11312 and the third capacitor 11313, the third diode 11323 may be disposed between the third capacitor 11313 and the fourth capacitor 11314, and the fourth diode 11324 may be disposed between the fourth capacitor 11314 and the first capacitor 11311.

When each of the plurality of capacitors 11310 is substantially the same capacitor as the capacitor 1310 of FIGS. 1 to 3, each of the plurality of diodes 11320 may be substantially the same diode as the diode 1320 of FIGS. 1 to 3. In some cases, when the plurality of capacitors 11310 have different capacitances, the type, characteristics, or size of the diode may be determined according to the capacitance of the connected capacitor 11310 for each of the plurality of diodes 11320. For example, the first diode 11321 having a relatively high current handling ability and a relatively high discharge capacity may be connected to the first capacitor 11311 having a relatively high capacitance, and the fourth diode 11324 having a relatively low current handling ability and a relatively low discharge capacity may be connected to the fourth capacitor 11314 having a relatively low capacitance.

When the plurality of capacitors 11310 have different capacitances, on the plane of the substrate 11301, the first diode 11321 may have the largest planar area among the plurality of diodes 11320, and the second diode 11322, the third diode 11323, and the fourth diode 11324 may have gradually decreasing planar areas. In some cases, the sum of the planar area of the first diode 11321 and the planar area of the fourth diode 11324 may be equal to the sum of the planar area of the second diode 11322 and the planar area of the third diode 11323. Therefore, even when the capacitances of the plurality of capacitors 11310 and the characteristics of the plurality of diodes 11320 become different from one another, the capacitor chip 11300 can maintain the same size and planar area. Accordingly, the semiconductor package 11000 according to one embodiment of the present disclosure can reduce manufacturing costs and process time of the capacitor chip 11300 including the plurality of capacitors 11310 having different capacitances and the plurality of diodes 11320 having different electrical characteristics.

By including the capacitor chip 11300 in which a different electrical path 11230 is connected to each of the plurality of capacitors 11310, the semiconductor package 11000 according to one embodiment of the present disclosure allows a signal to be transmitted to various electrical paths 11230 selected according to characteristics of a signal of chip-to-chip communication. In particular, when the plurality of capacitors 11310 have different capacitances, the semiconductor package 11000 can provide an optimal electrical path for different signals in various frequency bands with only one capacitor chip 11300.

Also, by including the capacitor chip 11300 in which the plurality of diodes 11320 are disposed between different pairs of the plurality of capacitors 11310, the semiconductor package 11000 according to one embodiment of the present disclosure allows a suitable diode to be placed according to characteristics of each of the plurality of capacitors 11310. Accordingly, by allowing a diode 11320 with a different current handling capacity or capacitance characteristic to be placed to correspond to each of the plurality of capacitors 11310 having different capacitances, the semiconductor package 11000 can implement an ESD protection structure that is optimized for capacity characteristics of each of the capacitors 11310. Therefore, by optimizing an overvoltage discharge path of each of the AC coupling capacitors, the semiconductor package 11000 can improve signal integrity and reliability.

According to any one of the problem solving means of the present disclosure, a semiconductor package includes a capacitor chip coupled between a first semiconductor die and a second semiconductor die, thereby blocking common-mode noise and improving electromagnetic interference (EMI) performance and signal integrity in chip-to-chip communication.

According to any one of the problem solving means of the present disclosure, a semiconductor package includes a capacitor chip on which a capacitor and a diode are integrated, thereby allowing the diode to effectively protect the capacitor from a surge signal introduced to a chip-to-chip communication line while the capacitor performs AC coupling of heterogeneous chips.

According to any one of the problem solving means of the present disclosure, a semiconductor package includes a capacitor chip on which a capacitor and a diode are formed on a single substrate, thereby reducing an area of a package substrate that is occupied by the capacitor and the diode and simplifying a package assembly process.

According to any one of the problem solving means of the present disclosure, a semiconductor package includes an AC-coupling capacitor chip on which a plurality of capacitors, which are connected in parallel and have different capacitances, are disposed, thereby allowing each capacitor to operate with an optimal signal transmission path in various frequency bands.

According to any one of the problem solving means of the present disclosure, a semiconductor package includes a capacitor chip on which a single diode is disposed between a plurality of capacitors, thereby simplifying a process of designing and manufacturing the capacitor chip.

According to any one of the problem solving means of the present disclosure, a semiconductor package includes a capacitor chip on which a different electrical path is connected to each of a plurality of capacitors, thereby providing an optimized electrical path for each signal in various frequency bands with only one capacitor chip.

According to any one of the problem solving means of the present disclosure, a diode with a different current handling capacity or capacitance characteristic is disposed to correspond to each of a plurality of capacitors having different capacitances in a semiconductor package, thereby implementing an ESD protection structure that is optimized for capacity characteristics of each capacitor.

Advantageous effects that can be obtained from the present disclosure are not limited to those mentioned above, and other unmentioned advantageous effects should be clearly understood by those of ordinary skill in the art to which the present disclosure pertains from the description above.

Although embodiments of the present disclosure have been described in more detail above with reference to the accompanying drawings, the present disclosure is not necessarily limited to these embodiments and may be modified in various ways without departing from the technical spirit of the present disclosure. Accordingly, the embodiments disclosed in the present disclosure are for describing, instead of limiting, the technical spirit of the present disclosure, and the scope of the technical spirit of the present disclosure is not limited by these embodiments. Therefore, the above-described embodiments should be understood as being illustrative, instead of limiting, in all aspects. The protection scope of the present disclosure should be construed based on the appended claims, and all the technical concepts in the equivalent scope thereof should be construed as falling within the scope of the present disclosure.

What is claimed is:

1. A semiconductor package comprising:
a package substrate;
a first semiconductor die disposed on the package substrate;
a second semiconductor die disposed to be spaced from the first semiconductor die on the package substrate; and
a capacitor chip disposed on at least one electrical path between the first semiconductor die and the second semiconductor die on the package substrate,
wherein the capacitor chip includes:
a substrate;
at least one trench capacitor disposed on the substrate; and
a diode disposed to be spaced from the at least one trench capacitor on the substrate,
one electrode of the at least one trench capacitor is connected to a cathode electrode of the diode and the first semiconductor die,
the other electrode of the at least one trench capacitor is connected to the second semiconductor die, and
an anode electrode of the diode is grounded.

2. The semiconductor package of claim 1, wherein the first semiconductor die and the second semiconductor die are heterogeneous chips having different driving voltages.

3. The semiconductor package of claim 1, wherein the diode includes:
a first doping region doped with an N-type impurity; and
a second doping region doped with a P-type impurity,
the first doping region is connected to the cathode electrode, and
the second doping region is connected to the anode electrode.

4. The semiconductor package of claim 3, wherein:
the diode further includes a P-type well region;
the first doping region and the second doping region are disposed in the P-type well region; and
the second doping region is disposed to be spaced from the first doping region to surround the first doping region and has a doping concentration higher than a doping concentration of the P-type well region.

5. The semiconductor package of claim 4, wherein:
the at least one trench capacitor is disposed in a plurality of first trenches located on the substrate;
the diode further includes a second trench disposed between the first doping region and the second doping region; and
the first trenches and the second trench are formed with the same process.

6. The semiconductor package of claim 3, wherein:
the first doping region and the second doping region are disposed in contact; and
the diode is a Zener diode.

7. The semiconductor package of claim 3, wherein:
the diode further includes an ohmic contact layer disposed on upper surfaces of the first doping region and the second doping region; and
the ohmic contact layer consists of a Ti/TiN stacking structure.

8. The semiconductor package of claim 3, wherein the diode is disposed to be surrounded by the at least one trench capacitor.

9. The semiconductor package of claim 3, wherein, at one side of the at least one trench capacitor, the diode is disposed along an edge of the one side.

10. The semiconductor package of claim 3, wherein the diode is disposed to surround the at least one trench capacitor.

11. The semiconductor package of claim 3, wherein:
the at least one trench capacitor includes a plurality of trench capacitors; and
the diode is disposed between the plurality of trench capacitors.

12. The semiconductor package of claim 11, wherein:
the plurality of trench capacitors are connected in parallel; and
the diode formed as one body is disposed between different pairs of the plurality of trench capacitors.

13. The semiconductor package of claim 11, wherein, when the at least one electrical path is provided as a plurality of electrical paths:
the plurality of electrical paths are connected to the capacitor chip; and
the plurality of electrical paths each connect the first semiconductor die and the second semiconductor die through one of the plurality of trench capacitors.
